(19) United States
(12) Patent Application Publication
(10) Pub. No.: US 2013/0334684 A1
(43) Pub. Date: Dec. 19, 2013

(54) SUBSTRATE STRUCTURE AND PACKAGE STRUCTURE

(71) Applicant: SILICONWARE PRECISION INDUSTRIES CO., L, Taichung (TW)

(72) Inventors: Chang-Fu Lin, Taichung (TW); Chin-Te Chen, Taichung (TW); Chin-Tsai Yao, Taichung (TW)

(73) Assignee: SILICONWARE PRECISION INDUSTRIES CO., LTD., Taichung (TW)

(21) Appl. No.: 13/654,780

(22) Filed: Oct. 18, 2012

(30) Foreign Application Priority Data
Jun. 19, 2012 (TW) 101121874

(51) Int. Cl. H01L 23/48

(52) U.S. Cl. 257/737; 257/734; 257/E23.01

(57) ABSTRACT

A substrate structure is provided, including a substrate body and a plurality of traces formed on a surface of the substrate body. At least one of the traces has an electrical contact formed in a groove thereof for electrically connecting an external element, thereby meeting the demands of fine line/fine pitch and miniaturization and improving the product yield.

### BACKGROUND OF THE INVENTION

1. Field of the Invention

The present invention relates to substrate structures and package structures, and, more particularly, to a substrate structure and a package structure for flip-chip packaging.

2. Description of Related Art

Increased miniaturization of electronic products requires circuit boards or packaging substrates to have fine lines/fine pitches.

FIGS. 1A and 1B show a substrate structure and a package structure according to the prior art. FIG. 1B is a top view and FIG. 1A is a cross-sectional view taken along a sectional line AA of FIG. 1B. Some components shown in FIG. 1A are omitted in FIG. 1B.

A substrate body 10, such as a packaging substrate or a circuit board is provided and a plurality of traces 11 are formed on a surface of the substrate body 10. Each of the traces 11 has a relatively wide electrical contact 111 formed at one end thereof for external electrical connection.

Further, a semiconductor chip 12 is provided. The semiconductor chip 12 has a plurality of electrode pads 121 formed on a surface thereof. An insulation layer 13 is formed on the surface of the semiconductor chip 12, and a plurality of openings 130 are formed in the insulation layer 13 for exposing the electrode pads 121. An under bump metallurgy (UBM) layer 14 is formed on each of the electrode pads 121, and a plurality of metal post 15 is formed on the UBM layer 14. A solder material 16 is formed on an end portion of the metal post 15. The semiconductor chip 12 is disposed on the substrate body 10 in a flip-chip manner such that the electrode pads 121 are electrically connected to the electrical contacts 111 of the traces 11 through the solder material 16.

However, since the electrical contacts 111 are wide, the pitches between the electrical contacts 111 become relatively small. Therefore, solder bridges can easily occur due to a positional deviation of the semiconductor chip 12 or bad flow control of the solder material 16 when it is heated to bond with the electrical contacts 111, thereby reducing the product reliability.

Therefore, how to overcome the above-described drawbacks has become critical.

### SUMMARY OF THE INVENTION

In view of the above-described drawbacks, the present invention provides a substrate structure, which comprises: a substrate body; and a plurality of traces formed on a surface of the substrate body, at least one of the traces having an electrical contact for electrically connecting an external element and the electrical contact being formed with a groove.

The present invention further provides a package structure, which comprises: a substrate body; a plurality of traces formed on a surface of the substrate body, at least one of the traces having an electrical contact for electrical connection of an external element and the electrical contact being formed with a groove; and a semiconductor chip having a plurality of electrode pads formed on a surface thereof and disposed on the substrate body via the surface having the electrode pads, wherein a conductive bump is formed on each of the electrode pads and has an end portion extended into the groove of the at least one of the traces and electrically connected to the at least one of the traces.

Therefore, by embedding the end portions of the conductive bumps in the corresponding grooves of the traces, the present invention improves the alignment precision, reduces the height of the overall package structure and prevents bridges from occurring between adjacent electrical contacts. Further, less underfill is required to be filled in areas between the semiconductor chip and the substrate body, thereby reducing the thickness of the overall package structure and the fabrication cost. Furthermore, since each of the conductive bumps connects a corresponding trace broken section of the trace, i.e., the groove of the trace, it leads to an increased contact area between the conductive bump and the trace, such that the bonding strength between the conductive bump and the trace is increased. Moreover, the present invention eliminates the need to increase the area of the electrical contacts as in the prior art and the solder material can be limited by the grooves so as to not to overflow, thus allowing a reduced pitch to be formed between the electrical contacts and the traces and consequently meeting the demands of fine line/fine pitch and improving the electrical performance of the package structure.

### BRIEF DESCRIPTION OF DRAWINGS

FIGS. 1A and 1B are schematic views showing a substrate structure and a package structure according to the prior art, wherein FIG. 1B is a top view and FIG. 1A is a cross-sectional view taken along a sectional line AA of FIG. 1B; and

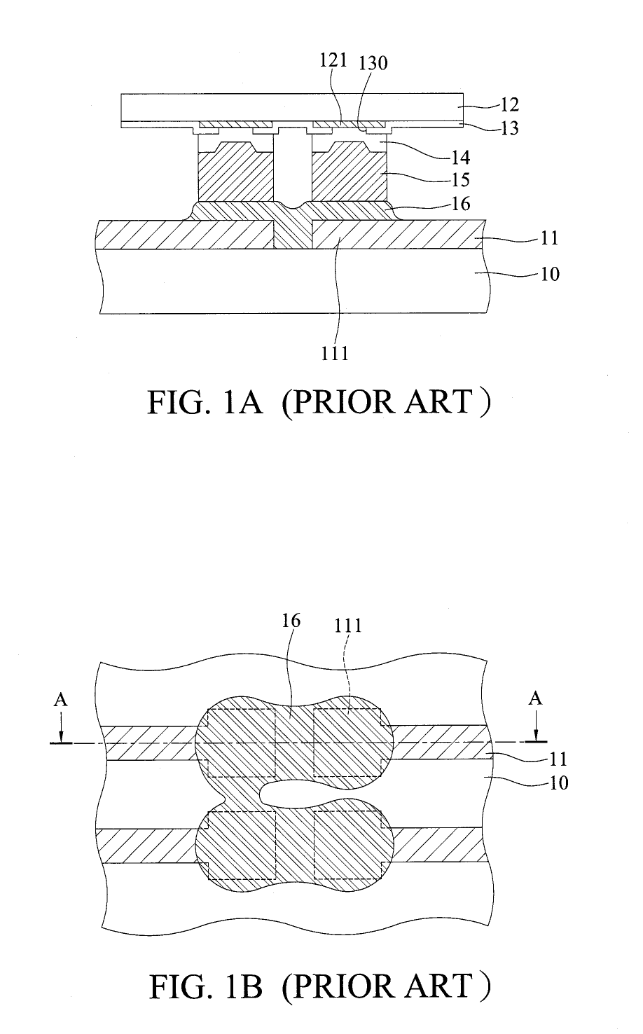

FIGS. 2A and 2B are schematic views showing a substrate structure and a package structure according to the present invention, wherein FIG. 2B is a top view and FIG. 2A is a cross-sectional view taken along a sectional line BB of FIG. 2B.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms such as “end”, “on”, “a” etc. are only used as a matter of descriptive convenience and not intended to have any other significance or provide limitations for the present invention.

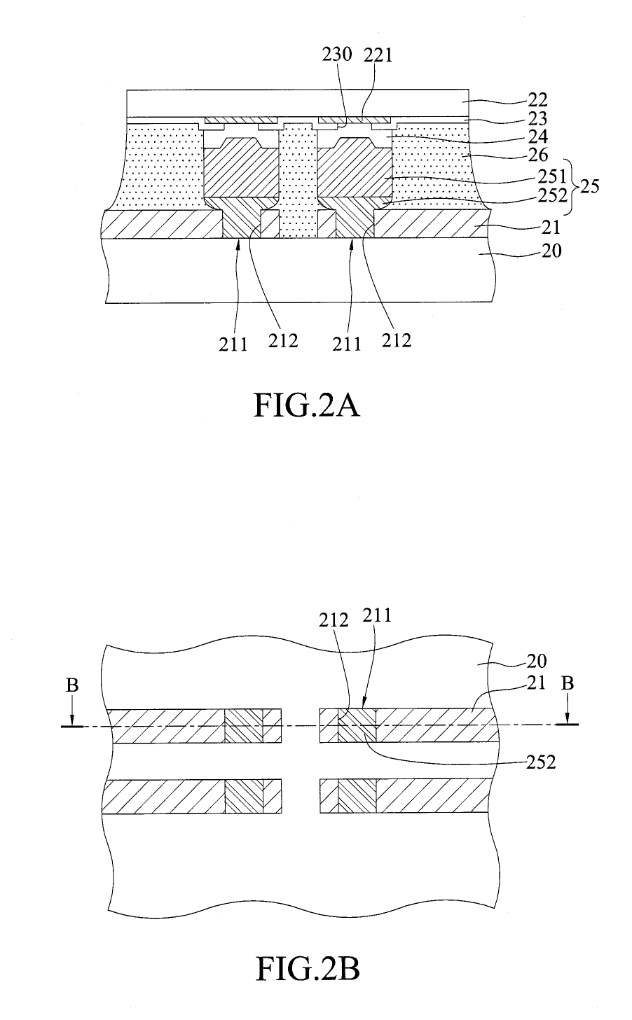

FIGS. 2A and 2B are schematic views showing a substrate structure and a package structure according to the present invention. FIG. 2B is a top view, and FIG. 2A is a cross-sectional view taken along a sectional line BB of FIG. 2B. Some components shown in FIG. 2A are omitted in FIG. 2B.

Referring to FIG. 2A, a substrate body 20, such as a packaging substrate or a circuit board is provided, and a plurality of traces 21 are formed on a surface of the substrate body 20. At least one of the traces 21 has an electrical contact 211 formed thereof for electrical connection of an external element and the electrical contact 211 is formed with a groove 212. The at least one of the traces is broken by the groove 212 such that a portion of the surface of the substrate body 20 is exposed through the groove 212 for external electrical connection.

Further, a semiconductor chip 22 is provided. The semiconductor chip 22 has a plurality of electrode pads 221 formed on a surface thereof. An insulation layer 23 is formed on the surface of the semiconductor chip 22, and a plurality of openings 230 are formed in the insulation layer 23 for exposing the electrode pads 221. An under bump metallurgy (UBM) layer 24 is formed on each of the electrode pads 221, and a conductive bump 25 is further formed on the UBM layer 24. The semiconductor chip 22 is flip-chip disposed on the substrate body 20 in a manner that end portions of the conductive bumps 25 correspond in position to the grooves 212 of the traces 21 so as to be electrically connected to the traces 21. An underfill 26 is formed between the semiconductor chip 22 and the substrate body 20.

In an embodiment, each of the conductive bumps 25 has a metal post 251 and a solder material 252 formed on one end of the metal post 251 and disposed in the corresponding groove 212. In other embodiments, the conductive bump 25 can be made of a solder material.

Referring to FIG. 2B, the end portion of each of the conductive bumps 25 is embedded in the corresponding groove 212 so as to connect the trace broken sections (side surfaces) of the trace 21.

The grooves 212 can be formed through a patterning process such as lithography. Each of the traces 21 can be completely broken by the groove 212 thereof, as shown in FIG. 2A. Alternatively, the groove 212 can be, for example, an opening that does not break the trace 21. In another embodiment, the groove 212 can be a U-shaped notch formed in the trace 21.

In an embodiment, the groove 212 can have a depth of approximately two-thirds the thickness of the trace 21. Since it can be easily understood by those skilled in the art upon reading the disclosure of the specification, detailed description is omitted herein.

Therefore, by embedding the end portions of the conductive bumps in the corresponding grooves of the traces, the present invention improves the alignment precision, reduces the height of the overall package structure and prevents bridges from occurring between adjacent electrical contacts. Further, less underfill is required to be filled in areas between the semiconductor chip and the substrate body, thereby reducing the thickness of the overall package structure and the fabrication cost. Since each of the conductive bumps connects the trace broken section of the trace, i.e., the groove of the trace, it leads to an increased contact area between the conductive bump and the trace, such that the bonding strength between the conductive bump and the trace is increased. Moreover, the present invention eliminates the need to increase the area of the electrical contacts as in the prior art and the solder material can be limited by the grooves so as to not to overflow, thus allowing a reduced pitch to be formed between the electrical contacts and the traces and consequently meeting the demands of fine line/fine pitch and improving the electrical performance of the package structure.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A substrate structure, comprising:
a substrate body; and
a plurality of traces formed on a surface of the substrate body, at least one of the traces having an electrical contact for electrically connecting an external element, wherein the electrical contact is formed with a groove.

2. The substrate structure of claim 1, wherein the groove is a trace broken section for a portion of the surface of the substrate body to be exposed therefrom.

3. The substrate structure of claim 1, wherein the substrate body is a packaging substrate or a circuit board.

4. A package structure, comprising:
a substrate body;
a plurality of traces formed on a surface of the substrate body, at least one of the traces having an electrical contact for electrically connecting an external element, wherein the electrical contact is formed with a groove; and
a semiconductor chip having a plurality of electrode pads formed on a surface thereof and disposed on the substrate body via the surface having the electrode pads, wherein a conductive bump is formed on each of the electrode pads and has an end portion extended into the groove of a corresponding one of the traces and electrically connected to the corresponding one of the traces.

5. The substrate structure of claim 4, wherein the groove is a trace broken section for a portion of the surface of the substrate body to be exposed therefrom.

6. The substrate structure of claim 4, wherein the end portion of the conductive bump is connected to the trace broken section of the at least one of the traces.

7. The substrate structure of claim 4, wherein the conductive bump comprises a metal post and a solder material formed on one end of the metal post and disposed in the groove of the corresponding one of the traces.

8. The substrate structure of claim 4, wherein the conductive bump is made of a solder material.

9. The substrate structure of claim 4, further comprising an underfill formed between the semiconductor chip and the substrate body.

10. The substrate structure of claim 4, further comprising an insulation layer formed on the surface of the semiconductor chip and having a plurality of openings for exposing the electrode pads.

11. The substrate structure of claim 4, further comprising an under bump metallurgy layer formed between the conductive bump and the corresponding electrode pad.

12. The substrate structure of claim 4, wherein the substrate body is a packaging substrate or a circuit board.
